(19) United States
(12) Patent Application Publication
(10) Pub. No.: US 2013/0252366 A1
(43) Pub. Date: Sep. 26, 2013

(54) ENERGY CONVERSION EFFICIENT THERMOELECTRIC POWER GENERATOR

(71) Applicant: KING FAHD UNIVERSITY OF PETROLEUM AND MINERALS, Dhahran (SA)

(72) Inventors: AHMET Z. SAHIN, Dhahran (SA); BEKIR S. YILBAS, Dhahran (SA)

(73) Assignee: KING FAHD UNIVERSITY OF PETROLEUM AND MINERALS, Dhahran (SA)

(21) Appl. No.: 13/901,421

(22) Filed: May 23, 2013

Related U.S. Application Data
(63) Continuation of application No. 13/333,747, filed on Dec. 21, 2011.
Application No. 13/333,747 is a continuation-in-part of application No. 12/897,633, filed on Oct. 4, 2010, now abandoned.

(51) Int. Cl. H01L 35/34

(52) U.S. Cl. CPC H01L 35/34
USPC 438/54

(57) ABSTRACT

The energy conversion efficient thermoelectric power generator includes a p-type thermoelectric element and an n-type thermoelectric element positioned adjacent the p-type thermoelectric element defining a gap therebetween, and first and second conductive members electrically connecting opposed top and the bottom ends of the p-type and n-type thermoelectric elements, respectively. The first conductive member forms a hot junction with the top ends of the p-type and n-type thermoelectric elements, and the second conductive member forms a cold junction with the bottom ends of the p-type and n-type thermoelectric elements. The materials and dimensions of the p-type and n-type thermoelectric elements are selected such that a slenderness ratio X of each falls within the range of 0≦X≦1.

### CROSS-REFERENCE TO RELATED APPLICATION

This application is a continuation of U.S. patent application Ser. No. 13/333,747, filed Dec. 21, 2011, pending, which is a continuation-in-part of U.S. patent application Ser. No. 12/897,633, filed Oct. 4, 2010, abandoned.

### BACKGROUND OF THE INVENTION

1. Field of the Invention

The present invention relates to thermoelectric power generators, and particularly to an energy conversion efficient thermoelectric power generator in which the choice of materials and dimensions of p-type and n-type thermoelectric elements in the thermoelectric power generator optimize the energy conversion efficiency thereof.

2. Description of the Related Art

The thermoelectric effect is the direct conversion of temperature differences to electric voltage and vice versa. A thermoelectric device creates a voltage when there is a different temperature on each side. Conversely, when a voltage is applied to the device, it creates a temperature difference (known as the Peltier effect). At atomic scale (specifically, charge carriers), an applied temperature gradient causes charged carriers in the material, whether they are electrons or electron holes, to diffuse from the hot side to the cold side, similar to a classical gas that expands when heated; this generates the thermally induced current.

This effect can be used to generate electricity, to measure temperature, to cool objects, or to heat them or cook them. Because the direction of heating and cooling is determined by the sign of the applied voltage, thermoelectric devices make very convenient temperature controllers. Traditionally, the term “thermoelectric effect” or “thermoelectricity” encompasses three separately identified effects; namely, the Seebeck effect, the Peltier effect, and the Thomson effect.

The Seebeck effect is the conversion of temperature differences directly into electricity. The Seebeck effect is the generation of voltage in the presence of a temperature difference between two different metals or semiconductors. This causes a continuous current in the conductors if they form a complete loop. Typically, the voltage created is of the order of several microvolts per Kelvin difference. One such combination, copper-constantan, has a Seebeck coefficient of 41 mV per Kelvin at room temperature.

In the circuit shown in FIG. 8, the voltage V is given by V=∫_{T}_{₁}^{T}^{₂}(S_{B}(T)−S_{A}(T))dT, where S_{A} and S_{B} are the Seebeck coefficients (sometimes referred to as the “thermoelectric power” or “thermopower”) of the metals A and B, respectively, as a function of temperature. T₁ and T₂ are, respectively, the temperatures of the two junctions. The Seebeck coefficients are non-linear as a function of temperature, and depend on the conductors' absolute temperature, material, and molecular structure. If the Seebeck coefficients are effectively constant for the measured temperature range, the above formula can be approximated as V=(S_{B}−S_{A})·(T₂−T₁).

The Seebeck effect is commonly used in thermocouples (so called, because they are made from a coupling or junction of materials, usually metals) to measure a temperature difference directly or to measure an absolute temperature by setting one end to a known temperature. A metal of unknown composition can be classified by its thermoelectric (TE) effect if a metallic probe of known composition, kept at a constant temperature, is held in contact with it. Industrial quality control instruments use this Seebeck effect to identify metal alloys. This is known as “thermoelectric alloy sorting”. Several thermocouples, when connected in series, are called a “thermopile”, which is sometimes constructed in order to increase the output voltage since the voltage induced over each individual couple is small. This is also the principle at work behind thermal diodes and thermoelectric generators (such as radioisotope thermoelectric generators, for example), which are used for creating power from heat differentials.

The “thermopower”, “thermoelectric power”, or Seebeck coefficient of a material measures the magnitude of an induced thermoelectric voltage in response to a temperature difference across that material. The thermopower has units of (V/K), though in practice it is more common to use microvolts per Kelvin. Values in the hundreds of μV/K, negative or positive, are typical of good thermoelectric materials.

The term “thermopower” is a misnomer since it measures the voltage or electric field induced in response to a temperature difference, rather than the electric power. An applied temperature difference causes charged carriers in the material, whether they are electrons or holes, to diffuse from the hot side to the cold side, similar to a classical gas that expands when heated. Mobile charged carriers migrating to the cold side leave behind their oppositely charged and immobile nuclei at the hot side thus giving rise to a thermoelectric voltage (“thermoelectric” refers to the fact that the voltage is created by a temperature difference).

Since a separation of charges also creates an electric potential, the buildup of charged carriers onto the cold side eventually ceases at some maximum value, since there exists an equal amount of charged carriers drifting back to the hot side as a result of the electric field at equilibrium. Only an increase in the temperature difference can resume a buildup of more charge carriers on the cold side and thus lead to an increase in the thermoelectric voltage. Incidentally, the thermopower also measures the entropy per charge carrier in the material. To be more specific, the partial molar electronic heat capacity is said to equal the absolute thermoelectric power multiplied by the negative of Faraday's constant.

The thermopower of a material S (sometimes also denoted as α) depends on the material's temperature and crystal structure. Typically, metals have small thermopowers because most have half-filled bands. Electrons (i.e., negative charges) and holes (positive charges) both contribute to the induced thermoelectric voltage, thus canceling each other's contribution to that voltage and making it small. In contrast, semiconductors can be doped with excess electrons or holes, and thus can have large positive or negative values of the thermopower depending on the charge of the excess carriers. The sign of the thermopower can determine which charged carriers dominate the electric transport in both metals and semiconductors.

If the temperature difference ΔT between the two ends of a material is small, then the thermopower of the material is defined (approximately) by

$$S = \frac{Δ V}{Δ T} ,$$

and a thermoelectric voltage ΔV is seen at the terminals. This can also be written in relation to the electric field E and the temperature gradient ∇T by the approximation

$$S = \frac{E}{∇ T} .$$

In practice, one rarely measures the absolute thermopower of the material of interest. This is because electrodes attached to a voltmeter must be placed onto the material in order to measure the thermoelectric voltage. The temperature gradient then also typically induces a thermoelectric voltage across one leg of the measurement electrodes. Therefore, the measured thermopower includes a contribution from the thermopower of the material of interest and the material of the measurement electrodes. The measured thermopower is then a contribution from both and can be written as

$${S}_{AB} = {S}_{B} - {S}_{A} = \frac{Δ {V}_{B}}{Δ T} - \frac{Δ {V}_{A}}{Δ T} .$$

Superconductors have zero thermopower, since the charged carriers produce no entropy. This allows a direct measurement of the absolute thermopower of the material of interest, since it is the thermopower of the entire thermocouple as well. In addition, a measurement of the Thomson coefficient μ of a material can also yield the thermopower through the relation

$$S = \int \frac{μ}{T} d T .$$

The thermopower is an important material parameter that determines the efficiency of a thermoelectric material. A larger induced thermoelectric voltage for a given temperature gradient will lead to a larger efficiency. Ideally, one would want very large thermopower values since only a small amount of heat is then necessary to create a large voltage. This voltage can then be used to provide power.

Charge carriers in the materials (electrons in metals, electrons and holes in semiconductors, ions in ionic conductors) will diffuse when one end of a conductor is at a different temperature from the other. Hot carriers diffuse from the hot end to the cold end, since there is a lower density of hot carriers at the cold end of the conductor. Cold carriers diffuse from the cold end to the hot end for the same reason. If the conductor were left to reach thermodynamic equilibrium, this process would result in heat being distributed evenly throughout the conductor. The movement of heat (in the form of hot charge carriers) from one end to the other is called a “heat current”. As charge carriers are moving, it is also an electrical current.

In a system where both ends are kept at a constant temperature difference (a constant heat current from one end to the other), there is a constant diffusion of carriers. If the rate of diffusion of hot and cold carriers in opposite directions were equal, there would be no net change in charge. However, the diffusing charges are scattered by impurities, imperfections, and lattice vibrations (i.e., phonons). If the scattering is energy dependent, the hot and cold carriers will diffuse at different rates. This creates a higher density of carriers at one end of the material, and the distance between the positive and negative charges produces a potential difference; i.e., an electrostatic voltage.

This electric field, however, opposes the uneven scattering of carriers, and an equilibrium is reached where the net number of carriers diffusing in one direction is canceled by the net number of carriers moving in the opposite direction from the electrostatic field. This means the thermopower of a material depends greatly on impurities, imperfections, and structural changes (which often vary themselves with temperature and electric field), and the thermopower of a material is a collection of many different effects.

Early thermocouples were metallic, but many more recently developed thermoelectric devices are made from alternating p-type and n-type semiconductor elements connected by metallic interconnects, as schematically illustrated in FIGS. 9A and 9B. Semiconductor junctions are especially common in power generation devices, while metallic junctions are more common in temperature measurement. Charge flows through the n-type element, crosses a metallic interconnect, and passes into the p-type element. If a power source is provided, the thermoelectric device may act as a cooler, as in the figure to the left below. This is the “Peltier effect”. Electrons in the n-type element will move opposite the direction of current and holes in the p-type element will move in the direction of current, both removing heat from one side of the device. If a heat source is provided, the thermoelectric device may function as a power generator, as in FIG. 9B. The heat source will drive electrons in the n-type element toward the cooler region, thus creating a current through the circuit. Holes in the p-type element will then flow in the direction of the current. The current can then be used to power a load, thus converting the thermal energy into electrical energy.

The Thomson effect was predicted (and subsequently experimentally observed) by William Thomson (also known as Lord Kelvin) in 1851. It describes the heating or cooling of a current-carrying conductor with a temperature gradient. Any current-carrying conductor (except for a superconductor), with a temperature difference between two points, will either absorb or emit heat, depending on the material.

The “figure of merit” for thermoelectric devices is defined as

$$Z = \frac{σ {S}^{2}}{κ} ,$$

where σ is the electrical conductivity, κ is the thermal conductivity, and S is the Seebeck coefficient or thermopower (conventionally in μV/K). This is more commonly expressed as the “dimensionless figure of merit” ZT by multiplying it with the average temperature ((T₂+T₁)/2). Greater values of ZT indicate greater thermodynamic efficiency, subject to certain provisions, particularly the requirement that the two materials of the couple have similar Z values. ZT is, therefore, a very convenient figure for comparing the potential efficiency of devices using different materials. Values of ZT=1 are considered good, and values of at least the 3-4 range are considered to be essential for thermoelectrics to compete with mechanical generation and refrigeration in efficiency.

The efficiency of a thermoelectric device for electricity generation is given by η, which is defined as the ratio of the energy provided to the load to the heat energy absorbed at the hot junction, or

$${η}_{ma x} = \frac{{T}_{H} - {T}_{C}}{{T}_{H}} \cdot \frac{\sqrt{1 + Z \overline{T}} - 1}{\sqrt{1 + Z \overline{T}} + \frac{{T}_{C}}{{T}_{H}}} \qquad ( 1 )$$

where T_{H} is the temperature at the hot junction and T_{C} is the temperature at the surface being cooled. Z T̅ is the modified dimensionless figure of merit, which now takes into consideration the thermoelectric capacity of both thermoelectric materials being used in the power-generating device, and is defined as

$$Z \overline{T} = \frac{{( {S}_{p} - {S}_{n} )}^{2} \overline{T}}{{[ {( {ρ}_{n} {κ}_{n} )}^{1 / 2} + {( {ρ}_{k} {κ}_{p} )}^{1 / 2} ]}^{2}} , \qquad ( 2 )$$

where ρ is the electrical resistivity, T̅ is the average temperature between the hot and cold surfaces, and the subscripts n and p denote properties related to the n- and p-type semiconducting thermoelectric materials, respectively. It should be noted that the efficiency of a thermoelectric device is limited by the Carnot efficiency (hence the T_{H} and T_{C} terms in ηₘₐₓ), since thermoelectric devices are still inherently heat engines.

It would obviously be desirable to produce a thermoelectric power generator having as great an energy efficiency as possible. Thus, an energy conversion efficient thermoelectric power generator solving the aforementioned problems is desired.

### SUMMARY OF THE INVENTION

The energy conversion efficient thermoelectric power generator includes a p-type thermoelectric element, an n-type thermoelectric element positioned adjacent the p-type thermoelectric element, but with a gap being defined therebetween, and first and second conductive members electrically connecting opposed top and the bottom ends of the p-type and n-type thermoelectric elements, respectively. The first conductive member forms a hot junction with the top ends of the p-type and n-type thermoelectric elements, and the second conductive member forms a cold junction with the bottom ends of the p-type and n-type thermoelectric elements.

An external load R_{L} is connected in parallel with the second conductive member. The slenderness ratio X for the p-type thermoelectric element and for the n-type thermoelectric element is given by

$$X = \frac{1}{\sqrt{{r}_{k} {r}_{ke}}} ,$$

and an external load parameter Y for the p-type thermoelectric element and for the n-type thermoelectric element is given by

$$Y = \sqrt{1 + {ZT}_{ave}} ( 1 + \sqrt{\frac{{r}_{k}}{{r}_{ke}}} ) ,$$

where rₖ is a ratio of a thermal conductivity of the p-type thermoelectric element to a thermal conductivity of the n-type thermoelectric element, and rₖₑ is a ratio of an electrical conductivity of the p-type thermoelectric element to an electrical conductivity of the n-type thermoelectric element. The materials and dimensions of the p-type and n-type thermoelectric elements are selected such that 0≦X≦1 for each of the p-type and n-type thermoelectric elements.

ZTₐᵥₑ is a figure of merit based on average temperature of the thermoelectric power generator given by

$${ZT}_{ave} = \frac{{α}^{2}}{{( \sqrt{\frac{{k}_{n}}{{k}_{e , n}}} + \sqrt{\frac{{k}_{p}}{{k}_{e , p}}} )}^{2}} ( \frac{{T}_{1} + {T}_{2}}{2} ) ,$$

where α is the Seebeck coefficient, T₁ is a temperature of the hot junction, T₂ is a temperature of the cold junction, kₙ is the thermal conductivity of the n-type thermoelectric element and kₚ is the thermal conductivity of the p-type thermoelectric element k_{e,n} is the electrical conductivity of the n-type thermoelectric element and k_{e,p} is the electrical conductivity of the p-type thermoelectric element.

As noted above, in order to enhance the energy conversion efficiency of the thermoelectric power generator, the materials and dimensions of the p-type and n-type thermoelectric elements are selected such that the ratio rₖ and the ratio rₖₑ produce a slenderness ratio X in the range of 0≦X≦1. Further, in order to greater enhance the efficiency, the ratio rₖ and the ratio rₖₑ are selected such that the slenderness ratio X for each of the p-type and n-type thermoelectric elements is approximately one. Additionally, the ratio rₖ, the ratio rₖₑ, and the electrical and thermal conductivities of the p-type and n-type thermoelectric elements are selected such that the external load parameter has a value of approximately three. The ratio rₖ may further be selected to have a value within the range of approximately one to approximately five.

These and other features of the present invention will become readily apparent upon further review of the following specification and drawings.

### BRIEF DESCRIPTION OF THE DRAWINGS

FIG. 1 is a schematic diagram of an energy conversion efficient thermoelectric power generator according to the present invention.

FIG. 2 is a graph illustrating variation of energy conversion efficiency with respect to slenderness ratio for differing load parameters.

FIG. 3 is a three-dimensional graph illustrating variation of energy conversion efficiency with respect to slenderness ratio for varying load parameters.

FIG. 4 is a graph illustrating variation of maximum energy conversion efficiency with respect to temperature ratio.

FIG. 5 is a three-dimensional graph illustrating variation of maximum energy conversion efficiency with respect to temperature ratio.

FIG. 6 is a graph illustrating optimal values of both the slenderness ratio and the external load parameter with respect to the thermal conductivity ratio.

FIG. 7 is a graph illustrating optimal values of both the slenderness ratio and the external load parameter with respect to the electrical conductivity ratio.

FIG. 8 is a schematic diagram illustrating a simple circuit of the prior art exhibiting the Seebeck effect.

FIGS. 9A and 9B schematically illustrate conventional thermocouples of the prior art formed from p- and n-type semiconductor elements connected by metallic interconnects.

FIGS. 10A and 10B are graphs showing efficiency of an exemplary Bi₂Te₃ thermoelectric generator as functions of slenderness ratio X and optimum external load parameter Y, respectively.

These and other features of the present invention will become readily apparent upon further review of the following specification and drawings.

### DETAILED DESCRIPTION OF THE PREFERRED EMBODIMENTS

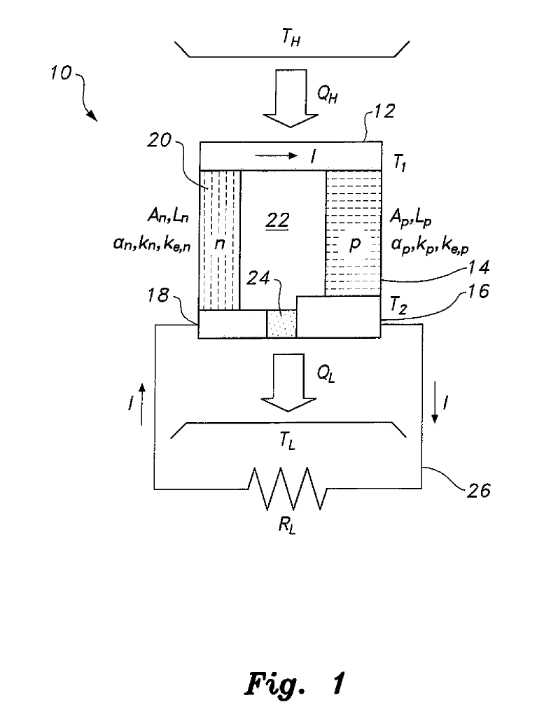

The energy conversion efficient thermoelectric power generator 10 of FIG. 1 is similar to the conventional prior art thermoelectric power generator shown in FIG. 9B. However, the thermoelectric power generator 10 exhibits improved energy conversion efficiency through the setting of the slenderness ratio according to the external load parameter. The slenderness ratio X is defined as

$$X = \frac{{A}_{p} / {L}_{p}}{{A}_{n} / {L}_{n}}$$

and the external load parameter Y is defined as

$$Y = \frac{{R}_{L}}{{L}_{n} / ( {k}_{e , n} {A}_{n} )} .$$

In the above, Aₚ and Aₙ are the cross-sectional areas of the p- and n-type thermoelectric elements 14, 20, respectively, Lₚ and Lₙ are the lengths of the p- and n-type thermoelectric elements 14, 20, respectively, R_{L} is the external load resistance and k_{e,n} is the electrical conductivity of the n-type thermoelectric element 20. As described above with reference to FIG. 9B, the p- and n-type elements 14, 20 are electrically connected to one another by metallic interconnects 12, 16, 18. Interconnects 16, 18 may include a semiconductor junction 24, as shown, with current/flowing through loop 26.

The energy conversion efficiency of the thermoelectric power generator device is improved (when compared to conventional thermoelectric power generators) through the thermodynamic optimization of operating and thermoelectric device parameters. The operating parameters include the temperature ratio

$$θ = \frac{{T}_{2}}{{T}_{1}}$$

and the external load parameter

$$Y = \frac{{R}_{L}}{{L}_{n} / ( {k}_{e , n} {A}_{n} )} .$$

The thermoelectric device parameters include the dimensionless figure of merit, as described above with reference to equation (2), which may be modified so that it is based on the average temperature as:

$${ZT}_{ave} = \frac{{α}^{2}}{{( \sqrt{\frac{{k}_{n}}{{k}_{e , n}}} + \sqrt{\frac{{k}_{p}}{{k}_{e , p}}} )}^{2}} ( \frac{{T}_{1} + {T}_{2}}{2} ) . \qquad ( 3 )$$

The thermoelectric device parameters further include the thermal conductivity ratio

$${r}_{k} = \frac{{k}_{p}}{{k}_{n}}$$

and electrical conductivity ratio

$${r}_{ke} = \frac{{k}_{e , p}}{{k}_{e , n}} .$$

A slenderness ratio of less than one results in high thermal efficiencies for certain external load parameter. For exemplary values of X=0.5, Y=1, θ=0.5, rₖ=1.0, rₖₑ=1.0 and ZTₐᵥₑ=1.5, the energy conversion efficiency of the thermoelectric power generator is approximately 8%. The energy conversion efficiency is more pronounced for larger values of the external load parameter. A typical value of 12.5% energy conversion efficiency results for exemplary values of X=0.5, Y=7, θ=0.5, rₖ=1.0, rₖₑ=1.0 and ZTₐᵥₑ=1.5. Increasing the thermal conductivity ratio increases the value of the maximum energy conversion efficiency.

Using a First Law of Thermodynamics analysis, the energy conversion efficiency for the thermoelectric power generator 10 can be written as:

$$η = \frac{{I}^{2} {R}_{L}}{α {IT}_{1} + K ( {T}_{1} - {T}_{2} ) - \frac{1}{2} {I}^{2} R} , \qquad ( 4 )$$

where

$$I = \frac{α ( {T}_{1} - {T}_{2} )}{{R}_{L} + R}$$

is the electrical current, α=αₚ−αₙ is the Seebeck coefficient,

$$K = \frac{{A}_{p} {k}_{p}}{{L}_{p}} + \frac{{A}_{n} {k}_{n}}{{L}_{n}}$$

is the overall thermal conductivity, and

$$R = \frac{{L}_{p}}{{A}_{p} {k}_{e , p}} + \frac{{L}_{n}}{{A}_{n} {k}_{e , n}}$$

is the overall electrical resistivity of the thermoelectric generator. In equation (4), T₁ and T₂ are the hot and cold junction temperatures, respectively, and R_{L} is the external load electrical resistance. Furthermore, A represents cross-sectional area, L represents length, k is the thermal conductivity and kₑ is the electrical conductivity of the thermoelectric elements, where the indices p and n indicate the p-type and n-type semiconductor elements 16, 20, respectively, in the thermoelectric generator 10.

The dimensionless quantities given below are utilized in the following analysis:

$$\begin{matrix}X = \frac{{A}_{p} / {L}_{p}}{{A}_{n} / {L}_{n}} ( i . e . , the slenderness ratio ) & ( 5 ) \\ Y = \frac{{R}_{L}}{{L}_{n} / ( {k}_{e , n} {A}_{n} )} ( i . e . , the external load parameter ) & ( 6 ) \\ {r}_{k} = \frac{{k}_{p}}{{k}_{n}} ( i . e . , the thermal conductivity ratio ) & ( 7 ) \\ {r}_{ke} = \frac{{k}_{e , p}}{{k}_{e , n}} ( i . e . , the electrical conductivity ratio ) & ( 8 )\end{matrix}$$

as well as the figure of merit (based on the average temperature in the thermoelectric generator), given by:

$${ZT}_{ave} = \frac{{α}^{2}}{{( \sqrt{\frac{{k}_{n}}{{k}_{e , n}}} + \sqrt{\frac{{k}_{p}}{{k}_{e , p}}} )}^{2}} ( \frac{{T}_{1} + {T}_{2}}{2} ) , \qquad ( 10 )$$

where T₁ and T₂ are the hot and cold junction temperatures, respectively.

The energy conversion efficiency given by equation (4) may be converted to a function of the above six dimensionless parameters as:

$$η = ( 1 - θ ) \frac{2 {{ZT}_{ave} ( 1 + \sqrt{\frac{{r}_{k}}{{r}_{ke}}} )}^{2}}{\begin{matrix}( 1 + θ ) Y ( {r}_{k} X + 1 ) {( 1 + \frac{R}{{R}_{L}} )}^{2} + \\ 2 {{ZT}_{ave} ( 1 + \sqrt{\frac{{r}_{k}}{{r}_{ke}}} )}^{2} [ 1 + ( \frac{1 + θ}{2} ) ( \frac{R}{{R}_{L}} ) ]\end{matrix}} , \\ where \\ \frac{R}{{R}_{L}} = \frac{1}{Y} ( \frac{1}{{r}_{ke} X} + 1 ) . \qquad ( 11 )$$

For certain n-type and p-type thermoelectric materials and operation temperatures, the dimensionless parameters rₖ, rₖₑ, ZTₐᵥₑ and θ can be fixed. The energy conversion efficiency can then be maximized with respect to the slenderness ratio X and external load parameter Y. With the fixed dimensionless parameters, the maximum energy conversion efficiency with respect to these parameters can be obtained as:

$$\{ \begin{matrix}\frac{\partial η}{\partial X} = 0 \\ \frac{\partial η}{\partial Y} = 0\end{matrix} \} \to \{ \begin{matrix}{X}_{opt} = \frac{1}{\sqrt{{r}_{k} {r}_{ke}}} \\ {Y}_{opt} = \sqrt{1 + {ZT}_{ave}} ( 1 + \sqrt{\frac{{r}_{k}}{{r}_{ke}}} )\end{matrix} \} . \qquad ( 12 )$$

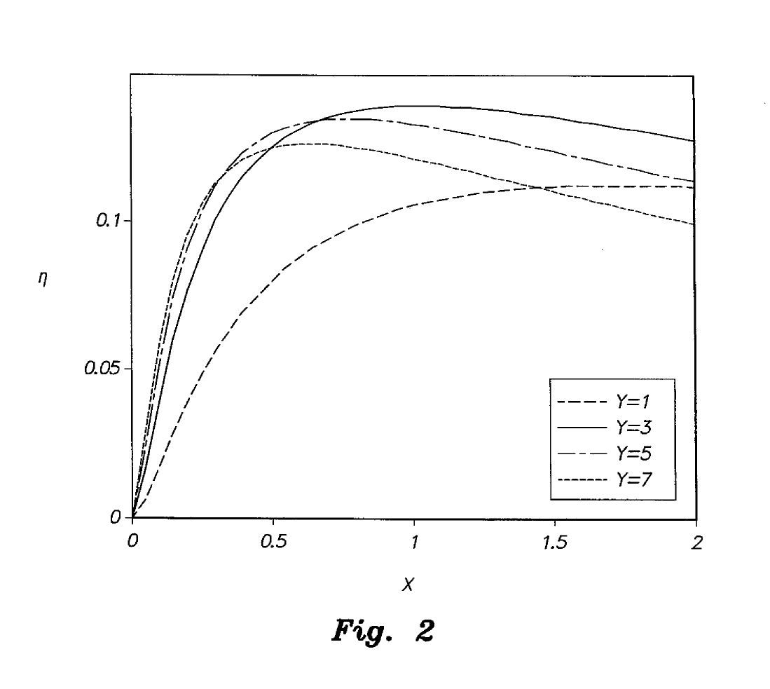

FIG. 2 shows the variation of energy conversion efficiency with respect to the slenderness ratio (given by equation (5)) for various external load parameters (equation (6)). It should be noted that the slenderness ratio is associated with the ratio of area to height of the semiconductor elements, while the external load parameter is related to the external load connected to the generator. Increasing slenderness ratio X towards one increases the energy conversion efficiency irrespective of the values of the load ratio considered. This behavior is associated with equation (11), where the term

$${Y ( {r}_{k} X + 1 ) [ 1 + \frac{1}{Y} ( \frac{1}{{r}_{k , e} X} + 1 ) ]}^{2}$$

becomes relatively small with increasing values of slenderness ratio X. Consequently, a slenderness ratio in the range of 0≦X≦1 enhances the energy conversion efficiency. In this case, the slenderness ratio of a p-type semiconductor, given by (Aₚ/Lₚ), is less than the slenderness ratio of an n-type semiconductor. FIG. 2 illustrates the variation of energy conversion efficiency with respect to the slenderness ratio for different external load parameters, including the values of θ=0.5, rₖ=1.0, rₖₑ=1.0 and, ZTₐ=1.5.

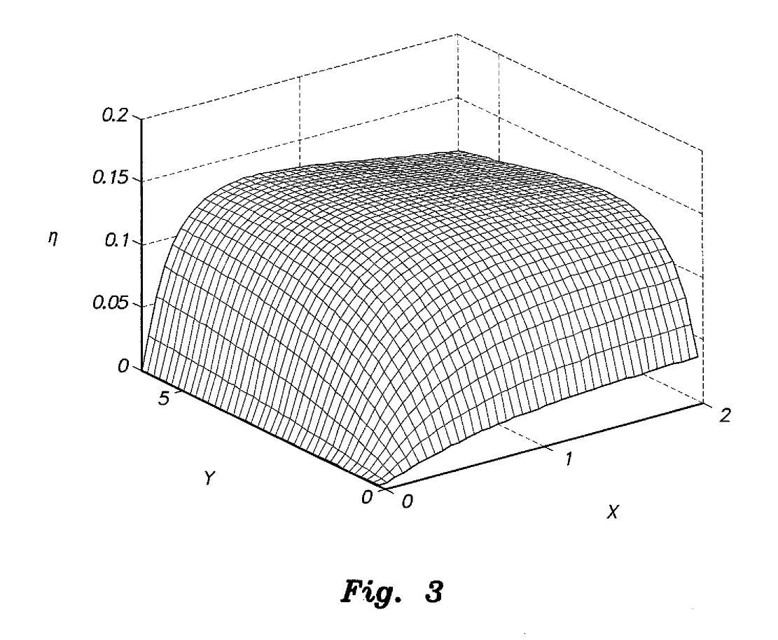

The rate of increase in the energy conversion efficiency changes with slenderness ratio in such a way that the rate of this increase enhances with an increasing load parameter. The maximum energy conversion efficiency occurs at different slenderness ratios for different external load parameters. This is due to the nonlinear behavior of energy conversion efficiency with respect to the slenderness ratio and external load parameter (as defined by equation (11)). Thus, a unique value of the maximum energy conversion efficiency occurs for a particular combination of slenderness ratio and the external load parameter. However, energy conversion efficiency reduces gradually with further increase of the slenderness ratio. This may be attributed to a nonlinear relationship between the energy conversion efficiency, the slenderness ratio, and the external load parameter (as in equation (11)). This effect is shown in FIG. 3 in the form of a three-dimensional plot of the energy conversion efficiency with respect to both the slenderness ratio and the load parameter. In FIG. 3, θ=0.5, rₖ=1.0, rₖₑ=1.0 and ZTₐᵥₑ=1.5.

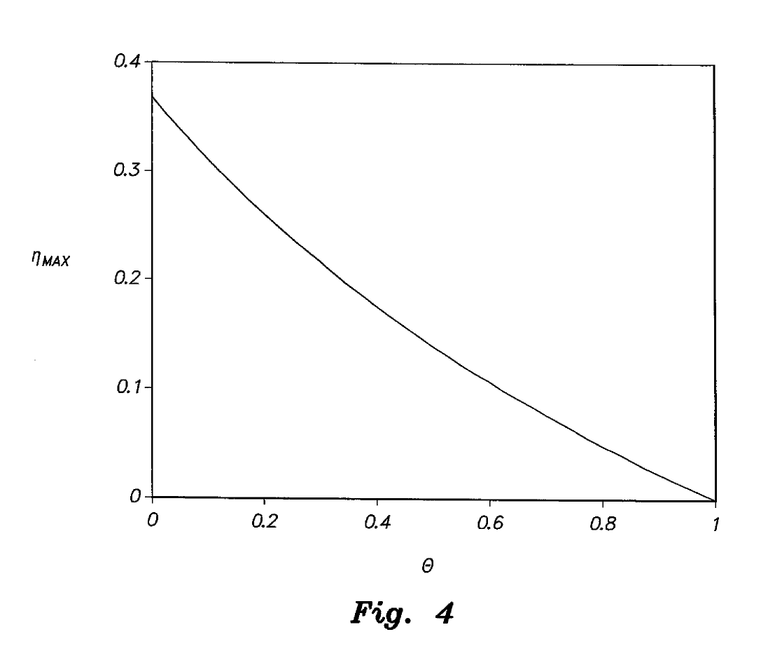

FIG. 4 shows the maximum energy conversion efficiency with respect to the temperature ratio for a fixed slenderness ratio of X=1 and a fixed external load parameter of Y=3. In FIG. 4, ZTₐᵥₑ=1.5. The maximum energy conversion efficiency reduces with an increasing temperature ratio

$$θ = \frac{{T}_{2}}{{T}_{1}} .$$

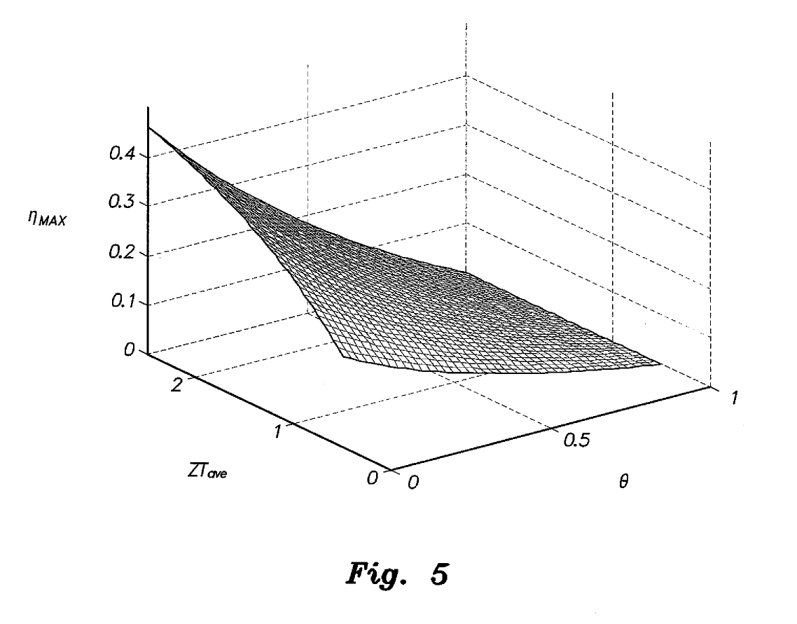

The maximum energy conversion efficiency is associated with the Carnot efficiency, which is given by 1-θ. Thus, increasing the temperature ratio lowers the Carnot efficiency and, consequently, the maximum energy conversion efficiency. It should be noted that the maximum energy conversion efficiency is always less than the Carnot efficiency. Further, the decay rate of the maximum energy conversion efficiency is not linear. Increasing the dimensionless figure of merit ZTₐᵥₑ enhances the maximum energy conversion efficiency. This can be seen in FIG. 5 in the form of a three-dimensional plot of the maximum energy conversion efficiency with respect to the temperature ratio and ZTₐᵥₑ.

For practical applications, the maximum ZTₐᵥₑ may have a value of approximately two, which, in turn, results in a maximum energy conversion efficiency on the order of 20% for a temperature ratio of 0.5. Reducing the temperature ratio further does not result in an excessive increase of the maximum energy conversion efficiency; e.g., the maximum energy conversion efficiency is on the order of 0.35 for ZTₐᵥₑ=2 and θ=0. This indicates that the maximum energy conversion efficiency achievable is limited to the range of approximately 0.2 to 0.25 for ZTₐᵥₑ=2. However, further reduction in ZTₐᵥₑ lowers the maximum energy conversion efficiency.

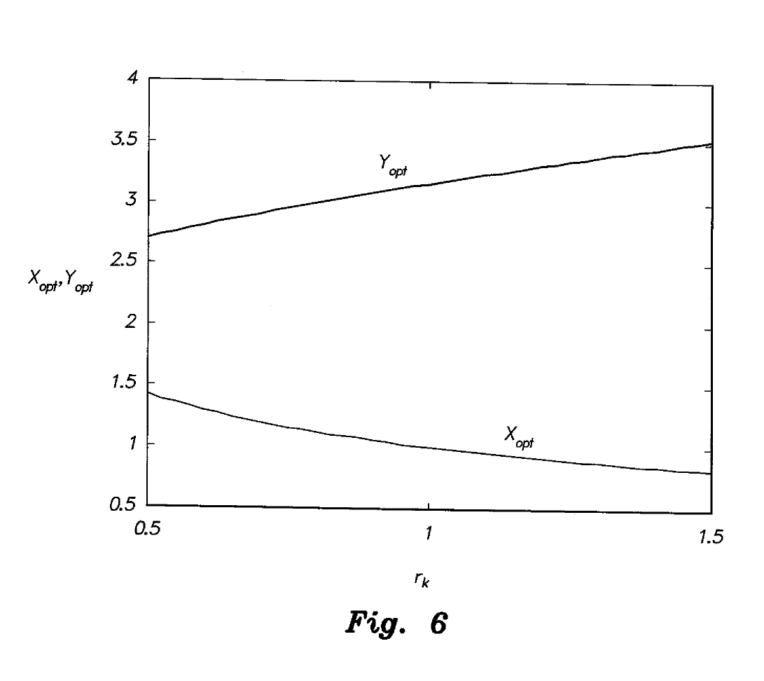

In order to assess the optimum values for the slenderness ratio and the load parameter, equation (12) is utilized. Further, the influence of the thermal conductivity ratio rₖ=kₚ/kₙ, on the optimum values of the slenderness ratio and the load parameter is shown in FIG. 6. It should be noted that increasing the thermal conductivity of the p-type semiconductor results in an increased thermal conductivity ratio, and increasing the thermal conductivity ratio lowers the optimum slenderness ratio while simultaneously increasing the optimum external load parameter. Additionally, a slenderness ratio on the order of one and a load ratio on the order of three results in the highest maximum energy conversion efficiency, as illustrated in FIG. 6. On the other hand, a thermal conductivity ratio on the order of 1-5 results in the highest maximum energy conversion efficiency. Thus, increasing the thermal conductivity of the p-type semiconductor almost 1-5 times of that corresponding to the n-type semiconductor is preferable for efficient design and operation of the thermoelectric power generator. In FIG. 6, rₖₑ=1.0 and ZTₐᵥₑ=1.5.

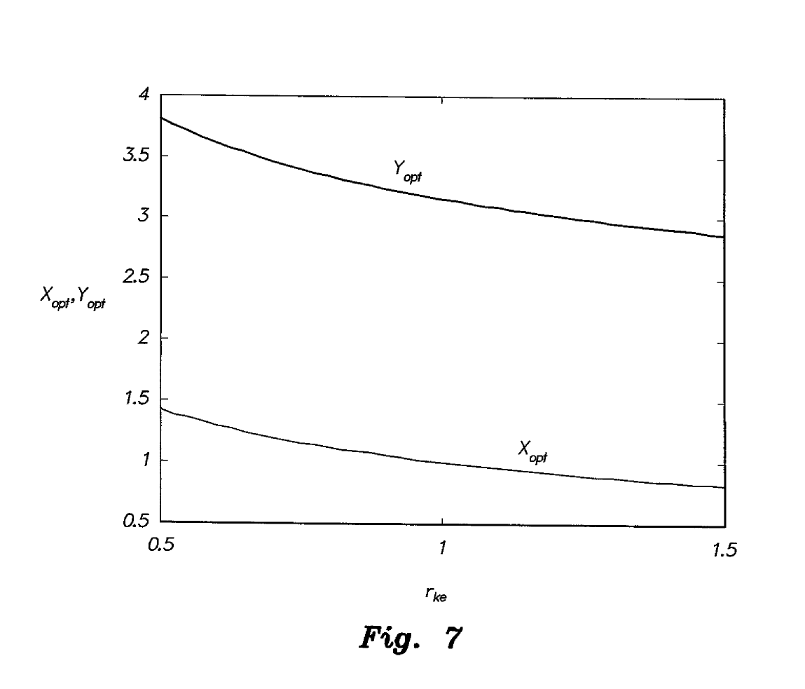

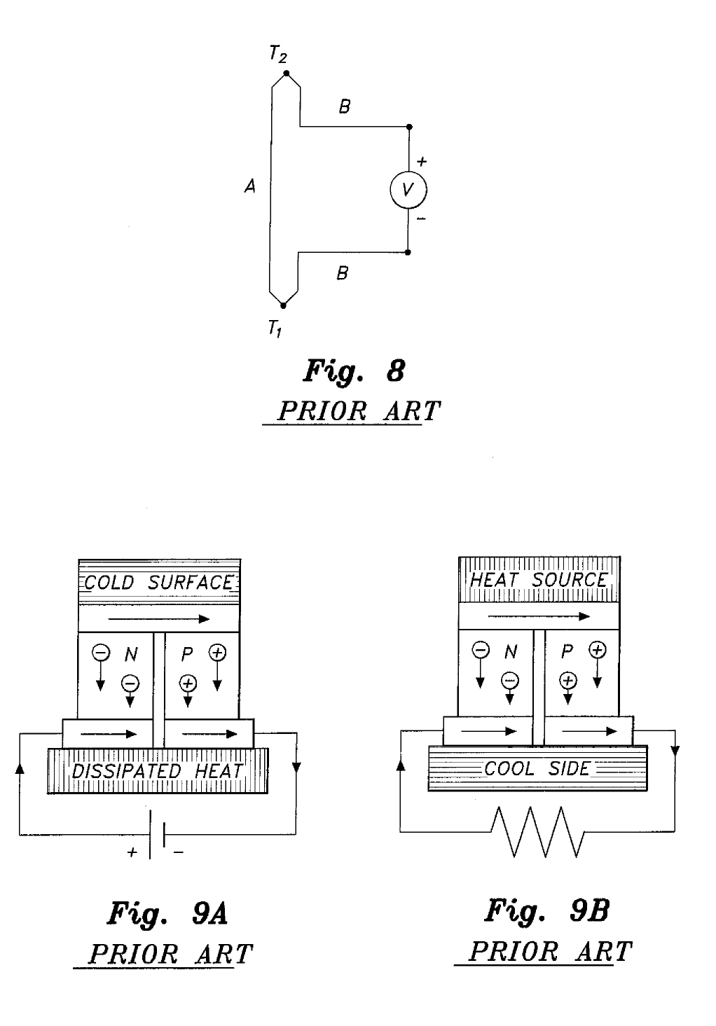

FIG. 7 illustrates the optimum values of the slenderness ratio and the load parameter with respect to the electrical conductivity ratio=r_{k,e}=k_{e,p}/k_{e,n}. Unlike that shown in FIG. 6, increasing the thermal conductivity ratio lowers both the optimum slenderness ratio and the optimum load parameter. This is due to equation (12), where the optimum slenderness and the optimum external load ratios are inversely proportional to the electrical conductivity ratio. Thus, the value of the maximum energy conversion efficiency reduces with an increasing electrical conductivity ratio due to reduction in the external load parameter. However, for the specific value of the electrical conductivity ratio, the value of the maximum energy conversion efficiency becomes high; e.g., rₖₑ=0.8, where the external load parameter is greater than or equal to three. Therefore, it is preferable for the electrical conductivity of the p-type semiconductor to remain lower than that corresponding to the n-type semiconductor in order to achieve high values of the maximum energy conversion efficiency. In FIG. 7, rₖ=1.0 and ZTₐᵥₑ=1.5.

The thermoelectric power generator 10 includes p-type thermoelectric element 14, n-type thermoelectric element 20 positioned adjacent the p-type thermoelectric element 14, but with a gap 22 being defined therebetween, and first and second conductive members 12 and 16, 18, 24 (forming a single conductive or partially semiconductive member) electrically connecting opposed top and the bottom ends of the p-type and n-type thermoelectric elements 14, 20, respectively. The first conductive member 12 forms a hot junction with the top ends of the p-type and n-type thermoelectric elements 14, 20, and the second conductive member forms a cold junction with the bottom ends of the p-type and n-type thermoelectric elements 14, 20.

An external load R_{L} is connected in parallel with the second conductive member. The slenderness ratio X for the p-type thermoelectric element and for the n-type thermoelectric element is given by

$$X = \frac{1}{\sqrt{{r}_{k} {r}_{ke}}} ,$$

and an external load parameter Y for the p-type thermoelectric element and for the n-type thermoelectric element is given by

$$Y = \sqrt{1 + {ZT}_{ave}} ( 1 + \sqrt{\frac{{r}_{k}}{{r}_{ke}}} ) ,$$

where rₖ is a ratio of a thermal conductivity of the p-type thermoelectric element to a thermal conductivity of the n-type thermoelectric element, and rₖₑ is a ratio of an electrical conductivity of the p-type thermoelectric element to an electrical conductivity of the n-type thermoelectric element. The materials and dimensions of the p-type and n-type thermoelectric elements are selected such that 0≦X≦1 for each of the p-type and n-type thermoelectric elements.

ZTₐᵥₑ is a figure of merit based on average temperature of the thermoelectric power generator, given by

$${ZT}_{ave} = \frac{{α}^{2}}{{( \sqrt{\frac{{k}_{n}}{{k}_{e , n}}} + \sqrt{\frac{{k}_{p}}{{k}_{e , p}}} )}^{2}} ( \frac{{T}_{1} + {T}_{2}}{2} ) ,$$

where α is the Seebeck coefficient, T₁ is a temperature of the hot junction, T₂ is a temperature of the cold junction, kₙ is the thermal conductivity of the n-type thermoelectric element and kₚ is the thermal conductivity of the p-type thermoelectric element k_{e,n} is the electrical conductivity of the n-type thermoelectric element and k_{e,p} is the electrical conductivity of the p-type thermoelectric element.

As noted above, in order to enhance the energy conversion efficiency of the thermoelectric power generator, the materials and dimensions of the p-type and n-type thermoelectric elements are selected such that the ratio rₖ and the ratio rₖₑ produce a slenderness ratio X in the range of 0≦X≦1. Further, in order to greater enhance the efficiency, the ratio rₖ and the ratio rₖₑ are selected such that the slenderness ratio X for each of the p-type and n-type thermoelectric elements is approximately one. Additionally, the ratio rₖ, the ratio rₖₑ, and the electrical and thermal conductivities of the p-type and n-type thermoelectric elements are selected such that the external load parameter has a value of approximately three. The ratio rₖ may further be selected to have a value within the range of approximately one to approximately five.

In the above, Tₐᵥₑ is determined from

$$\frac{{T}_{1} + {T}_{2}}{2} ,$$

where T₁ is the hot junction temperature and T₂ is the cold junction temperature. Thus, Tₐᵥₑ varies between approximately 135° C. and approximately 310° C., depending on the thermoelectric materials used in the thermoelectric device. For example, for Bi₂Te₃, Tₐᵥₑ is approximately 135° C., while skutterudite has a Tₐᵥₑ of approximately 310° C.

Additionally, the efficiency of a thermoelectric generator device, given above, can be rewritten as:

$$η = ( 1 - θ ) \frac{2 {{ZT}_{ave} ( 1 + \sqrt{\frac{{r}_{k}}{{r}_{ke}}} )}^{2}}{\begin{matrix}( 1 + θ ) Y ( {r}_{k} X + 1 ) {( 1 + \frac{R}{{R}_{L}} )}^{2} + \\ 2 {{ZT}_{ave} ( 1 + \sqrt{\frac{{r}_{k}}{{r}_{ke}}} )}^{2} [ 1 + ( \frac{1 + θ}{2} ) ( \frac{R}{{R}_{L}} ) ]\end{matrix}} \\ where \\ \frac{R}{{R}_{L}} = \frac{1}{Y} ( \frac{1}{{r}_{ke} X} + 1 ) . \qquad ( 13 )$$

The optimum values of the slenderness ratio Xₒₚₜ and the external load parameter Yₒₚₜ that yield a maximum efficiency are given by:

$${X}_{opt} = {( \frac{{A}_{p} / {L}_{p}}{{A}_{n} / {L}_{n}} )}_{opt} = \frac{1}{\sqrt{{r}_{k} {r}_{ke}}}$$

$$and$$

$${Y}_{opt} = {( \frac{{R}_{L}}{{L}_{n} / ( {k}_{e , n} {A}_{n} )} )}_{opt} = \sqrt{1 + {ZT}_{avg}} ( 1 + \sqrt{\frac{{r}_{k}}{{r}_{ke}}} ) ,$$

respectively. As an example, a thermoelectric generator made from bismuth-telluride (Bi₂Te₃) is considered.

In this example, the thermoelectric generator operates between hot and cold temperatures of T₁=600° C. and T₂=300° C., respectively. In this case, the temperature ratio is θ=0.5 and the average temperature Tₐᵥₑ=450° C. The thermoelectric properties of Bi₂Te₃ and the calculated values of the optimum slenderness ratio Xₒₚₜ and the optimum external load parameter Yₒₚₜ are shown below in Table 1:

TABLE 1
TABLE 1: Thermoelectric properties and calculated values for Bi₂Te₃

| kₑₙ | kₑₚ | kₙ | kₚ | Z | ZTₐᵥₑ | rₖ | rₖₑ | Xₒₚₜ | Yₒₚₜ |
|---|---|---|---|---|---|---|---|---|---|
| 1.205 | 1 | 0.023 | 0.019 | 0.0023 | 1.035 | 0.826 | 0.83 | 1.21 | 2.85 |

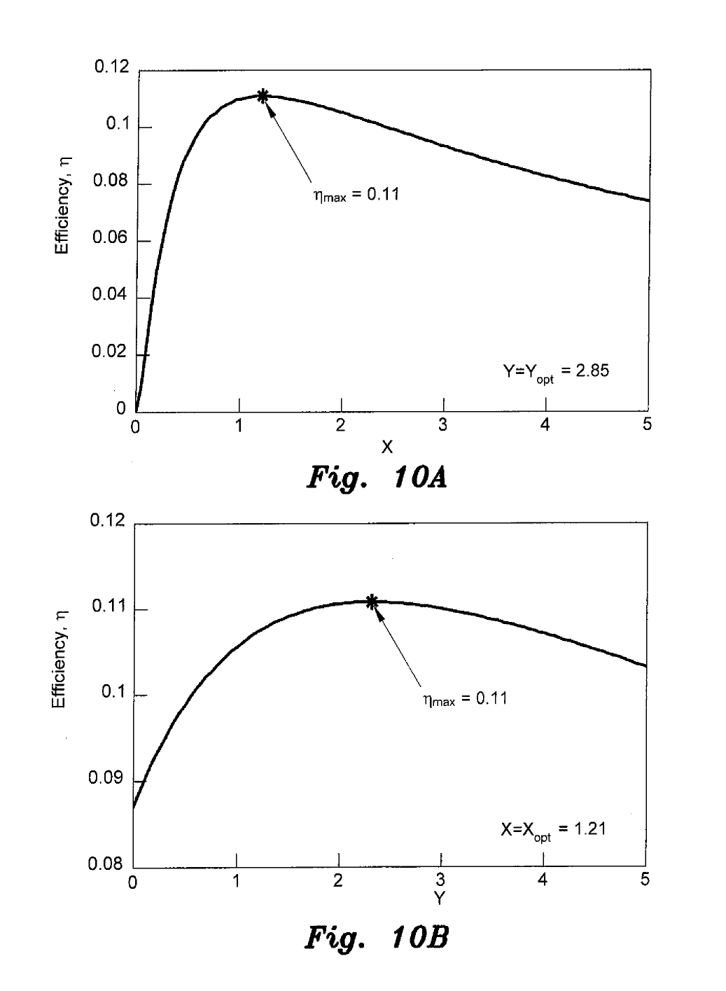

Deviations from both the optimum slenderness ratio of Xₒₚₜ=1.21 and the optimum external load parameter Yₒₚₜ=2.85 cause decreases in the efficiency of the thermoelectric device according to equation (13), which can also be seen in FIGS. 10A and 10B.

In the above example, although the optimal value for Y is clearly shown to be below though near three, as predicted, the value for X is outside the preferred range of 0≦X≦1. It should be understood that the properties vary greatly for different materials, and Bi₂Te₃ is merely one example. Table 2 below illustrates thermodynamic and calculated properties for a range of different materials:

TABLE 2
Thermoelectric properties and calculated values for selected
materials

Material

| Parameter/ | | | Bismuth- | |
|---|---|---|---|---|
| Value | Bi₂Te₃ | Silicon | Antimony | Si₇Ge₃ |
| kₑₙ | 1.205 | 0.2 | 8.33 | 0.95 |
| kₑₚ | 1 | 0.17 | 23.8 | 1.25 |
| kₙ | 0.023 | 1.09 | 0.08 | 0.05 |
| kₚ | 0.019 | 1 | 0.2 | 0.06 |
| Z | 0.0023 | 0.00013 | 0.00087 | 0.0015 |
| ZTₐᵥₑ | 1.035 | 0.06 | 0.392 | 0.675 |
| rₖ | 0.826 | 0.92 | 2.41 | 1.16 |
| rₖₑ | 0.83 | 0.85 | 2.86 | 1.31 |
| Xₒₚₜ | 1.21 | 1.13 | 0.38 | 0.81 |
| Yₒₚₜ | 2.85 | 2.1 | 2.26 | 2.51 |

As noted above, in order to enhance the energy conversion efficiency of the thermoelectric power generator, the materials and dimensions of the p-type and n-type thermoelectric elements are selected such that the ratio rₖ and the ratio rₖₑ produce a slenderness ratio X in the range of 0≦X≦1. Further, in order to greater enhance the efficiency, the ratio rₖ and the ratio rₖₑ are selected such that the slenderness ratio X for each of the p-type and n-type thermoelectric elements is approximately one. Additionally, the ratio rₖ, the ratio rₖₑ, and the electrical and thermal conductivities of the p-type and n-type thermoelectric elements are selected such that the external load parameter has a value of approximately three. The ratio rₖ may further be selected to have a value within the range of approximately one to approximately five. Deviations from these calculated ranges and values are found to decrease the efficiency of the thermoelectric device according to equation (13).

It is to be understood that the present invention is not limited to the embodiments described above, but encompasses any and all embodiments within the scope of the following claims.

1-3. (canceled)

4. A method of making a thermoelectric power generator, comprising:
selecting a p-type thermoelectric element and an n-type thermoelectric element to each have an optimal slenderness ratio X such that X is approximately greater than or equal to 0.3 and less than or equal to 1.0, wherein the optimal slenderness ratio X given by
$$X = \frac{1}{\sqrt{{r}_{k} {r}_{ke}}} ,$$
where rₖ is a ratio of a thermal conductivity of the p-type thermoelectric element to a thermal conductivity of the n-type thermoelectric element, and rₖₑ is a ratio of an electrical conductivity of the p-type thermoelectric element to an electrical conductivity of the n-type thermoelectric element;
positioning the n-type thermoelectric element adjacent the p-type thermoelectric element, the p-type and n-type thermoelectric elements defining a gap therebetween;
electrically connecting opposed top and the bottom ends of the p-type and n-type thermoelectric elements with first and second conductive members, respectively, the first conductive member forming a hot junction with the top ends of the p-type and n-type thermoelectric elements, the second conductive member forming a cold junction with the bottom ends of the p-type and n-type thermoelectric elements; and
connecting an external load in parallel with the second conductive member.

5. The method of making a thermoelectric power generator as recited in claim 4, wherein the step of selecting the p-type thermoelectric element and the n-type thermoelectric element further comprises selecting the ratio rₖ, the ratio rₖₑ, and the electrical and thermal conductivities of the p-type and n-type thermoelectric elements such that an optimal external load parameter Y has a value between approximately two and approximately three, wherein the optimal external load parameter Y is given by
$$Y = \sqrt{1 + {ZT}_{ave}} ( 1 + \sqrt{\frac{{r}_{k}}{{r}_{ke}}} ) ,$$
where ZTₐᵥₑ is a figure of merit based on average temperature of the thermoelectric power generator given by
$${ZT}_{ave} = \frac{{α}^{2}}{{( \sqrt{\frac{{k}_{n}}{{k}_{e , n}}} + \sqrt{\frac{{k}_{p}}{{k}_{e , p}}} )}^{2}} ( \frac{{T}_{1} + {T}_{2}}{2} ) ,$$
where α is the Seebeck coefficient, T₁ is a temperature of the hot junction, T₂ is a temperature of the cold junction, kₙ is the thermal conductivity of the n-type thermoelectric element and kₚ is the thermal conductivity of the p-type thermoelectric element k_{e,n} is the electrical conductivity of the n-type thermoelectric element, k_{e,p} is the electrical conductivity of the p-type thermoelectric element, and
$${T}_{ave} = \frac{{T}_{1} + {T}_{2}}{2} .$$

6. The method of making a thermoelectric power generator as recited in claim 5, wherein the step of selecting the p-type thermoelectric element and the n-type thermoelectric element further comprises selecting the ratio rₖ to have a value within the range of approximately one to approximately three.
